(19) United States
(12) Patent Application Publication
(10) Pub. No.: US 2013/0075946 A1
(43) Pub. Date: Mar. 28, 2013

(54) METHOD OF FABRICATING MICRO STRUCTURED SURFACES WITH ELECTRICALLY CONDUCTIVE PATTERNS

(71) Applicant: Robert J. Petcavich, The Woodlands, TX (US)

(72) Inventor: Robert J. Petcavich, The Woodlands, TX (US)

(73) Assignee: UNIPIXEL DISPLAYS, INC., The Woodlands, TX (US)

(21) Appl. No.: 13/698,854

(22) PCT Filed: Apr. 29, 2011
(86) PCT No.: PCT/US11/34500

§ 371 Date: Dec. 7, 2012

Related U.S. Application Data
(60) Provisional application No. 61/331,287, filed on May 4, 2010.

(51) Int. Cl. H05K 3/00

(52) U.S. Cl. CPC H05K 3/0082
USPC 264/104

(57) ABSTRACT

A method comprises forming a first pattern on a first flat surface and forming an inverse of the pattern on a second flat surface. The method further comprises attaching the second flat surface to a roller to produce an embossing tool and applying pressure between the embossing tool and a substrate thereby forming a second pattern in the substrate. The substrate is coated with a radiation curable resin material. The method also comprises transferring ink to the substrate, the ink containing a catalyst, and coating the substrate with the second pattern in an electroless plating bath. The first pattern alternatively may be formed on a sleeve which is then attached to a drum/roller.

### TECHNICAL FIELD

The present disclosure pertains to methods for producing electrical circuitry. In particular the methods include the use of a radiation curable resin that can be electroless plated with a variety of metals for use in electronic applications.

### BACKGROUND

A printed circuit board, or PCB, is used to mechanically support and electrically connect electronic components pathways, tracks or traces etched from copper sheets laminated onto a non-conductive substrate. It is also referred to as printed wiring board (PWB) or etched wiring board. A PCB populated with electronic components is a printed circuit assembly (PCA), also known as a printed circuit board assembly (PCBA).

Materials that may make up a PCB are conducting layers that are typically made of thin copper foil. Insulating layers or dielectrics are typically laminated together with epoxy resin prepreg. The board is typically coated with a solder mask. A number of different dielectrics are available that can provide different insulating values depending on the requirements of the circuit. Such dielectrics include polytetrafluoroethylene (Teflon), FR-4, FR-1, CEM-1 or CEM-3. Prepreg materials used in the PCB industry include FR-2 (Phenolic cotton paper), FR-3 (Cotton paper and epoxy), FR-4 (Woven glass and epoxy), FR-5 (Woven glass and epoxy), FR-6 (Matte glass and polyester), G-10 (Woven glass and epoxy), CEM-1 (Cotton paper and epoxy), CEM-2 (Cotton paper and epoxy), CEM-3 (Woven glass and epoxy), CEM-4 (Woven glass and epoxy), and CEM-5 (Woven glass and polyester). Thermal expansion is a design consideration especially with BGA and naked die technologies, and glass fiber offers dimensional stability.

Many printed circuit boards are made by bonding a layer of copper over the entire substrate, sometimes on both sides, (creating a “blank PCB”) then removing unwanted copper after applying a temporary mask (e.g. by etching), leaving only the desired copper traces. Some PCBs are made by adding traces to the bare substrate (or a substrate with a very thin layer of copper) usually by a complex process of multiple electroplating steps.

There are three common “subtractive” methods (methods that remove copper) used for the production of printed circuit boards. Silk Screen Printing uses etch-resistant inks to protect the copper foil. Photoengraving uses a photomask and chemical etching to remove the copper foil from the substrate. The photomask is usually prepared with a photo plotter from data produced by a technician using CAM, or computer-aided manufacturing software. Laser-printed transparencies are typically employed for phototools; however, direct laser imaging techniques are being employed to replace phototools for high-resolution requirements. Finally, PCB board milling uses a two or three-axis mechanical milling system to physically abraid away the copper foil from the substrate. A PCB milling machine (referred to as a ‘PCB Prototyper’) operates in a similar way to a plotter, receiving commands from the host software that control the position of the milling head in the x, y, and (if relevant) z axis. Data to drive the Prototyper is extracted from files generated in PCB design software and stored in HPGL or Gerber file format.

“Additive” processes also exist. The most common is the “semi-additive” process. In this process, the unpatterned board has a thin layer of copper already on it. A reverse mask is then applied. (Unlike a subtractive process mask, this mask exposes those parts of the substrate that will eventually become the traces.) Additional copper is then plated onto the board in the unmasked areas; copper may be plated to any desired weight. Tin-lead or other surface plating's are then applied. The mask is stripped away and a brief etching step removes the now-exposed original copper laminate from the board, isolating the individual traces. The additive process is commonly used for multi-layer boards as it facilitates the plating through the holes (to produce conductive vias) in the circuit board.

However, the problem shared by all of the above mentioned fabrication methods are they use a copper foil already laminated to the substrate or plated substrate surface and numerous process steps are necessary to produce a finished PCB board. Such processes are both labor and materials intensive and generally waste a considerable amount of copper.

### SUMMARY

Various embodiments of the invention are directed to a method comprising forming a first pattern on a first flat surface and forming an inverse of the pattern on a second fiat surface. The method further comprises attaching the second flat surface to a roller to produce an embossing tool and applying pressure between the embossing tool and a substrate thereby forming a second pattern in the substrate, The substrate is coated with a radiation curable resin material. The method also comprises transferring ink to the substrate, the ink containing a catalyst, and coating the substrate with the second pattern in an electroless plating bath.

Other embodiments are directed to a method comprising forming a first pattern on a first flat surface and forming an inverse of the pattern on a second flat surface. Such methods further comprise attaching the second flat surface to a roller to produce an embossing tool and applying pressure between the embossing tool and a substrate thereby forming a second pattern in the substrate. The substrate is coated with a radiation curable resin material. The method also comprises coating the substrate with the second pattern in an electroless plating bath. In such methods the resin may or may not comprise an organometallic material suitable for the plating process. In embodiments in which the organometallic material is not included in the resin, a catalyst-based ink is transferred to the substrate to function as the seed layer for the plating process.

### BRIEF DESCRIPTION OF THE DRAWINGS

Various features, aspects, and advantages of the present invention will become better understood when the following detailed description is read with reference to the accompanying figures in which like characters represent like parts throughout the figures, wherein:

FIG. 1 shows a method in accordance with a first embodiment of the invention;

FIG. 2 shows a cross sectional view of a micro embossed conductive traces on a substrate;

FIG. 3 shows a method in accordance with a second embodiment of the invention; and

FIG. 4 shows a method in accordance with a third embodiment of the invention.

### DETAILED DESCRIPTION OF SPECIFIC EMBODIMENTS

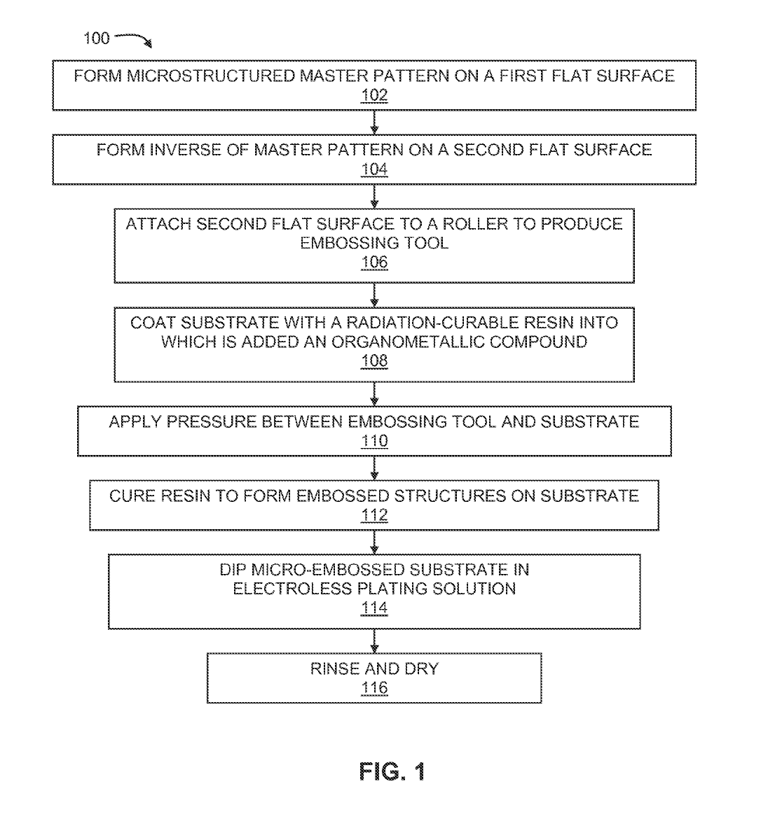

FIG. 1 illustrates a method 100 in accordance with various embodiments. In this and the other methods described herein, the order of the actions can be as shown or varied from that shown. Further, the actions may all be performed sequentially, or two or more of the actions may be performed in parallel.

At 102, the method comprising forming a microstructured master pattern on a first flat surface. This pattern will eventually be embossed onto the substrate of interest. The master pattern is generally created on glass or rigid polymeric substrates by any of a variety of known photolithographic processes. The pattern feature size of the master on the surface can vary from 0.1 to 50 microns in the x, y and z planes of the three dimensional geometric pattern. In other embodiments, the master pattern is formed directly on a drum (as opposed to a flat surface) or on a sleeve that is then mounted around a drum. In such embodiments, a shim is not needed.

Once the master is fabricated as in 102, an inverse pattern is created on a second flat surface as in 104 where the master pattern is copied onto either a polymeric or metal substrate or “shim”. The shim can be rigid or flexible and can range in thickness from 12 to 1,000 microns with 100-300 being preferred. The shim is then attached to a rigid roller as in 106, generally a metal drum, by means of a pressure sensitive adhesive or welding. The combination of the second flat surface and the roller now forms the embossing tool that will allow for fabrication of the structures onto the substrate of interest. If sleeves are formed as explained above, the sleeve is mounted to the drum by creating a temperature differential between them so that the sleeve is slightly larger than the drum.

Fabrication of the electrically conductive micro-embossed substrate of interest begins at 108 where the substrate to be embossed is coated with a thin liquid layer of radiation curable resin. The substrate of interest can be inorganic or organic and in the preferred embodiment is polymeric sheet or film. In some embodiments, the resin comprises a blend of monomers, oligomers and/or polymers which may also contain a solvent to reduce the viscosity to allow for ease of fabrication. In this embodiment, the radiation curable resin mixture preferably contains an organometallic additive that acts as a seed layer for subsequent electroless plating of metallic conductors. The organometallic material may comprise palladium acetate in a concentration range, for example, from 0.01% to 5%, with 1% to 1.5% being preferred, by weight of seed material to weight of solids in the radiation curable resin mixture. The thin liquid coating containing the organometallic additive may be thermally treated prior to micro-embossing to remove excess solvent and or assist with lowering the viscosity of the resin blend on the surface of the substrate to improve wetting.

At 110, the method comprises applying pressure between the embossing tool created at 106 and the resin-coated substrate. Application of pressure eliminates any excess liquid resin an air bubbles and any air bubbles that may be trapped between the embossing tool and the substrate of interest.

After the leveling and squeezing process of 110, the method 100 comprises curing the resin while the substrate is still in imitate contact with the embossing tool. Curing the resin causes the resin to harden into a solid polymeric structure having the inverse geometric shape as the master tool pattern.

Upon exposure to ionizing radiation as in 110 the organometallic additive in the resin becomes active and allows the polymeric microstructures to be electroless plated with metal from a solution. The micropatterned surface of the substrate is then dipped into a plating solution (114) whereupon a catalytic reaction occurs between the palladium and metal in the electroless plating solution. The metal in the plating solution is deposited onto the surface of the substrate. In various embodiments, the metal in the plating solution comprises any suitable type of metal such as copper, nickel, gold, silver, etc. Any of a variety of plating solutions can be used. In some embodiments, the plating solution used is ENPLATE 406, a commercial product supplied by Cookson Electronics, Enthone Products. After metal plating has occurred, the now electrically conductive micro-embossed substrate is rinsed with water to remove any residual plating solution and dried (116).

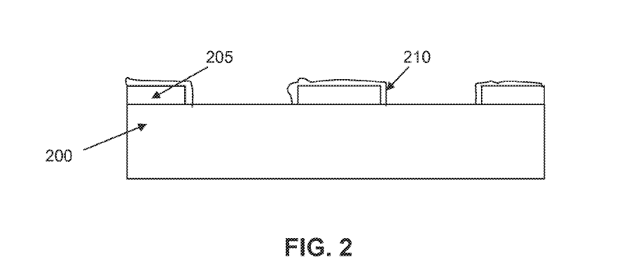

FIG. 2 shows a cross section of a finished micro-embossed electrically conductive geometric shape such as a line trace. Substrate 200 may comprise glass, polymer fiberglass prepreg or polymer film. The micro-embossed pattern 205 is covered with metal plating 210 that is deposited by the electroless plating solution. The thickness of the metal plating 210 preferably ranges from 5 nanometers to 100 microns.

The micro-embossed electrically conductive patterned substrate can be used as-is or cut into any size and shape required to produce a finished electronic product such as a flex circuit, PWB, transparent touch screen, RFID antennas, and flexible transistor components.

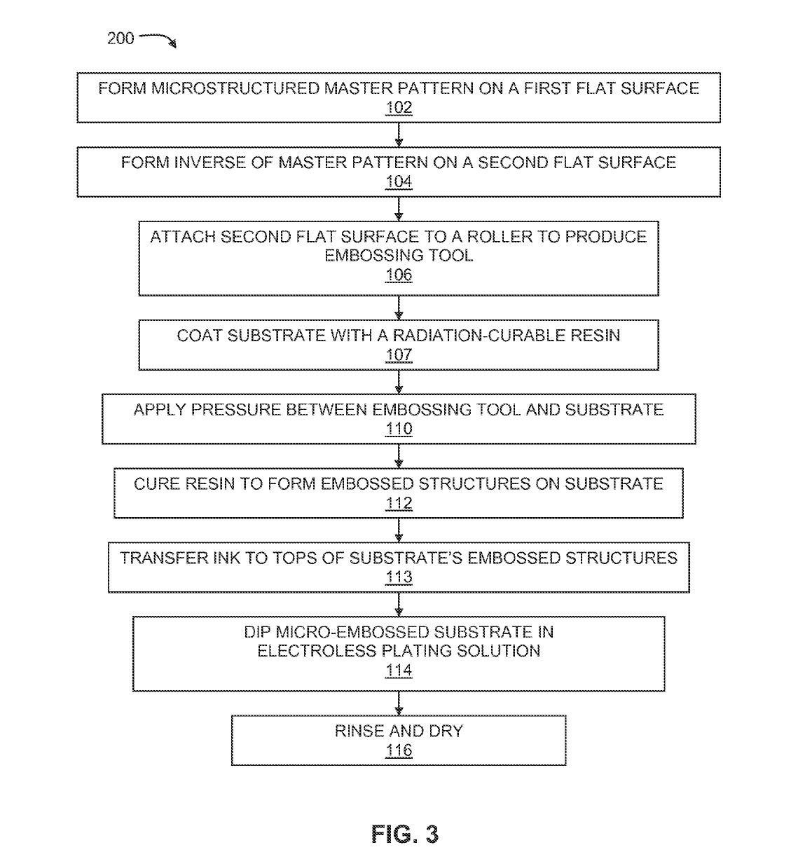

FIG. 3 shows a method 200 in accordance with a second embodiment. The method 200 includes some of the same actions as in method 100 of FIG. 1, and the common actions have the same reference numerals for convenience. Actions 102, 104, and 106 in FIG. 3 are the same as in FIG. 1 whereby the master pattern and inverse patterns are formed on the first and second surfaces and then second surface is then attached to a roller to produce the embossing tool. A difference is that action 106 from FIG. 1 has been replaced with action 107 in which the substrate is coated with a radiation-curable resin, and preferably a resin that does not have an organometallic compound. Instead, after applying pressure between the embossing tool and the substrate (110) and curing the resin (112), a polymer catalyst-based ink is transferred in 113 to the tops of the substrate's structures formed during actions 110, 112. Transferring the ink can be accomplished in a variety of ways such as by flexographic, micro-gravure, or intaglio printing. The catalyst in the ink provides the material to which the metal can be plated in 114. The substrate is then rinsed and dried at 116.

Thus, for the method 100 in FIG. 1, the resin includes the material necessary for plating to occur, whereas for the method 200 in FIG. 3, the resin has no such material and instead a catalyst-based ink is applied to the substrate to provide the seed layer for plating to occur.

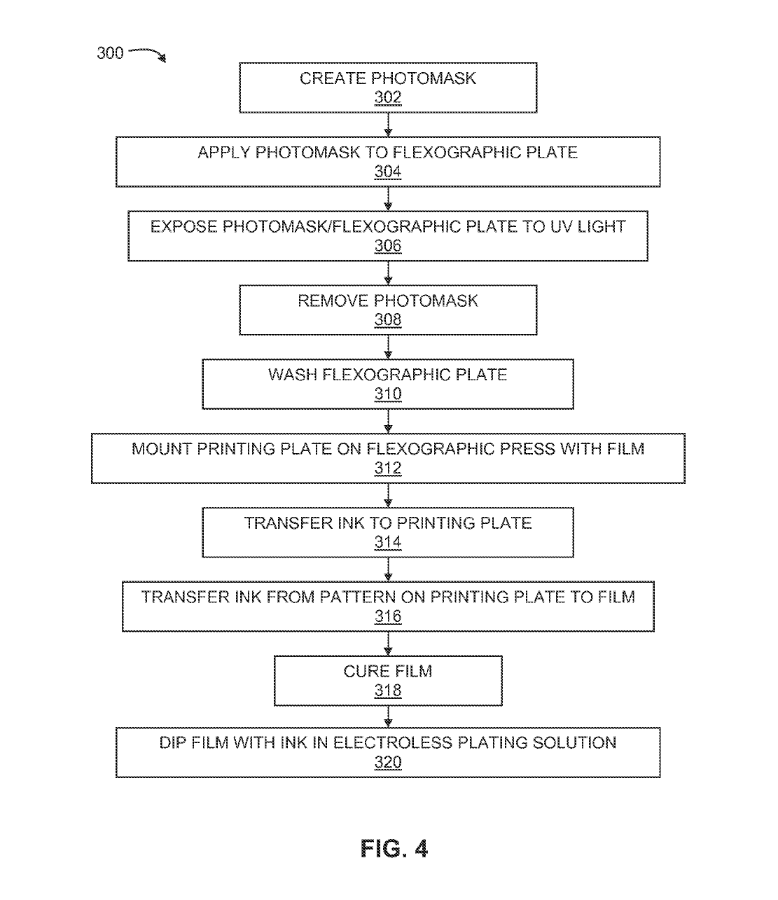

FIG. 4 shows another method 300 in accordance with a third embodiment. At 302, a photomask is created preferably with an inverse image of the pattern desired. The photomask may be made from any suitable material such as glass with a chrome image. At 304, the photomask is applied to a flexographic plate. Applying the photomask to the flexographic plate may comprise laminating the photomask to the flexographic plate. The flexographic plate may be made from any suitable material such as substrate on which a photo emulsion is provided. Application of the photomask to the flexographic plate preferably uses sufficient pressure to squeeze any trapped air.

At 306, the combination of photomask and flexographic plate is exposed to radiation (e.g., UV light). Where the UV light shines through the photomask (in areas with no chrome image), the UV light crosslinks the photo emulsion on the flexographic plate thereby hardening the emulsion. In areas on the photomask containing the chrome image, the UV light cannot pass through and the underlying photo emulsion on the flexographic plate remains in a more liquid state (i.e., does not become crosslinked and hardened).

The photomask is then removed at 308 and the flexographic plate is washed at 310. Washing the plate removes the non-crosslinked emulsion thereby leaving the hardened emulsion on the flexographic plate. At this point, the flexographic plate contains the image representing the desired electrical connective pathways and is called a “printing plate.”

The printing plate is mounted on a flexographic press also loaded with a film (312). The film comprises any suitable film such as PET, Cellulosic, Polycarbonate, Polymide, or Polyolefin. At 314, the method further comprises transferring a polymer catalyst-based ink through the flexographic press to the printing plate and then from the printing plate to the film (316).

After the ink has been fully transferred to the film and thereby covers various portions of the image corresponding to the target image, the film is cured at 318. This curing process may include the application of, for example, heat or UV radiation. The curing process hardens the ink. At 320, the cured film is dipped into an electroless plating solution, such as that described above.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

1. A method, comprising:
forming a first pattern on a first flat surface;
forming an inverse of the pattern on a second flat surface;
attaching the second flat surface to a ropier to produce an embossing tool;
applying pressure between the embossing tool and a substrate thereby forming a second pattern in the substrate, wherein the substrate is coated with a radiation curable resin material; and
coating the substrate with the second pattern in an electroless plating bath.

2. The method of claim 1 wherein the radiation curable resin material does not include an organometallic compound and the method further comprises transferring a catalyst-based ink onto the substrate before coating the substrate in the electroless plating bath.

3. The method of claim 1 further comprising transferring a catalyst-based ink onto the substrate before coating the substrate in the electroless plating bath.

4. The method of claim 1, wherein the radiation curable resin material comprises an organometallic compound.

5. The method of claim 1 further comprising curing the substrate with the second pattern to produce a cured structure on the substrate,

6. The method of claim 5 wherein coating the substrate comprises coating the cured structure on the substrate.

7. The method of claim 1 further comprising applying pressure between the embossing tool and the substrate.

8. A method, comprising:
forming a first pattern on a first flat surface;
forming an inverse of the pattern on a second flat surface;
attaching the second flat surface to a roller to produce an embossing tool;
applying pressure between the embossing tool and a substrate thereby forming a second pattern in the substrate, wherein the substrate is coated with a radiation curable resin material;
transferring ink to at least a portion of the substrate, said ink containing a catalyst; and
coating the substrate with the second pattern in an electroless plating bath.

9. The method of claim 8 wherein the radiation curable resin material does not include an organometallic compound.

10. The method of claim 8 further comprising curing the substrate.

11. A method, comprising:
creating a photomask;
applying the photomask to a flexographic plate;
exposing the photomask and flexographic plate to radiation to produce a printing plate based on said flexographic plate; and
transferring a catalyst-based ink to the printing plate.

12. The method of claim 11 further comprising transferring ink from the printing plate to a film.

13. The method of claim 12 further comprising curing said film.

14. The method of claim 13 further comprising coating the film in an electroless plating bath.

15. The method of claim 11 wherein applying the photomask to the flexographic plate comprises laminating the photomask to the flexographic plate.

16. A method, comprising forming a first pattern on a sleeve;
mounting said sleeve around a drum thereby forming an embossing tool;
applying pressure between the embossing tool and a substrate thereby forming a second pattern in the substrate, wherein the substrate is coated with a radiation curable resin material; and
coating the substrate with the second pattern in an electroless plating bath.

17. The method of claim 16 wherein mounting said sleeve around said drum comprising creating a temperature differential between said sleeve and drum.
